(19) United States
(12) Patent Application Publication
(10) Pub. No.: US 2011/0168432 A1
(43) Pub. Date: Jul. 14, 2011

(54) METHOD FOR PRODUCING AN ELECTRICALLY CONDUCTIVE PATTERN, AND AN ELECTRICALLY CONDUCTIVE PATTERN PRODUCED THEREBY

(75) Inventors: Sang-Ki Chun, Daejeon (KR); Dong-Wook Lee, Daejeon (KR); In-Seok Hwang, Daejeon (KR); Seung-Wook Kim, Giheung-gu (KR)

(73) Assignee: LG CHEM, LTD., Seoul (KR)

(21) Appl. No.: 13/119,322

(22) PCT Filed: Sep. 17, 2009
(86) PCT No.: PCT/KR2009/005306

§ 371 Date: Mar. 16, 2011

(30) Foreign Application Priority Data
Sep. 17, 2008 (KR) 10-2008-0091253

(51) Int. Cl. H05K 1/00; B41F 33/00; G02B 5/22

(52) U.S. Cl. 174/254; 101/483; 174/250; 359/885

(57) ABSTRACT

Provided are a method for producing an electrically conductive pattern, and an electrically conductive pattern produced by the method, the method including the steps of: a) forming an electrically conductive pattern on a substrate, and b) blackening the surface of the electrically conductive pattern by immersing the electrically conductive pattern in a halogen solution which oxidizes the surface of the electrically conductive pattern.

### TECHNICAL FIELD

The present invention relates to a method for producing an electrically conductive pattern whereby the electrically conductive pattern may be blackened and an electrically conductive pattern produced thereby, and more particularly, to a method for producing an electrically conductive pattern whereby a surface of the electrically conductive pattern may be blackened by oxidizing the electrically conductive pattern and the electrically conductive pattern produced thereby. This application claims the priority of Korean Patent Application No. 10-2008-0091253 filed on Sep. 17, 2008, in the Korean Intellectual Property Office, the entirety of the contents of which are hereby incorporated by reference.

### BACKGROUND ART

In general, a display device, collectively referring to a TV, a computer monitor or the like, includes a display assembly having a display panel that forms an image, and a casing that supports the display assembly.

The display assembly includes an image-forming display panel such as a cathode ray tube (CRT), a liquid crystal display (LCD) or a plasma display panel (PDP), a circuit board for driving the display panel, and an optical filter positioned in front of the display panel.

The optical filter includes: an anti-reflective layer that prevents external light, incident from the outside, from being reflected back to the outside; a near-infrared shielding layer that shields near-infrared rays generated from the display panel in order to prevent the malfunction of an electronic device such as a remote controller; a color compensation layer that increases color purity by including color adjusting dyes to control color tone; and an electromagnetic wave shielding film for shielding electromagnetic waves generated from the display panel during the operation of the display device.

Herein, the electromagnetic wave shielding film is composed of a substrate made of a transparent material, and a metallic material having excellent electrical conductivity such as silver, copper or the like, and the electromagnetic wave shielding film includes an electrically conductive pattern which is patterned by photolithography.

Since the electrically conductive pattern is formed of a metallic material having a high luster, external light incident from the outside, or image light from the display panel may be reflected to thereby reduce a contrast ratio. Therefore, in order to suppress these phenomena, the surface of the electrically conductive pattern is commonly black. That is, the electrically conductive pattern is generally blackened.

As an example of a blackening treatment method for an electrically conductive pattern, carbon black or a black dye is added to a conductive paste that is used for forming the electrically conductive pattern.

As other examples of a blackening treatment method for an electrically conductive pattern, Korean Patent Application Publication No. 2004-0072993 and Japanese Patent Application Publication No. 2001-210988 disclose that a mesh is formed over a metal foil by photolithography and the mesh is then blackened using chemicals such as concentrated nitric acid or the like.

### DISCLOSURE

### Technical Problem

Since carbon black is much higher in specific resistivity than metals included in a conductive paste, and a black dye has no conductivity, the carbon black or black dye will act as impurities when added to conductive paste. Although the carbon black and black dye can supply a certain degree of blackening in final products, electromagnetic wave shielding ability is decreased as sheet resistance is greatly increased, due to the carbon black and black dye.

Also, in the case in which an electrically conductive pattern is formed and then the electrically conductive pattern is blackened through treatment by concentrated nitric acid, there are problems that workability becomes poor, treatment time is long, and a sufficient degree of blackening may not be provided. Further, there is also a problem of increasing sheet resistance, which has an effect on electromagnetic wave shielding ability.

### Technical Solution

According to an aspect of the present invention, there is provided a method for producing an electrically conductive pattern including: forming an electrically conductive pattern on a substrate and blackening a surface of the electrically conductive pattern by immersing the electrically conductive pattern in a halogen solution to oxidize the surface of the electrically conductive pattern.

According to another aspect of the present invention, there is provided an electrically conductive pattern produced by the method according to the present invention.

According to another aspect of the present invention, there is provided a film including the electrically conductive pattern produced by the method according to the present invention.

According to another aspect of the present invention, there is provided an optical filter for a display device including the electrically conductive pattern produced by the method according to the present invention.

According to another aspect of the present invention, there is provided a display device including the electrically conductive pattern produced by the method according to the present invention.

According to another aspect of the present invention, there is provided a film including: a substrate; an electrically conductive pattern provided on the substrate; and a blackened layer formed on a surface of the electrically conductive pattern by immersing the electrically conductive pattern in a halogen solution to oxidize the surface of the electrically conductive pattern.

### Advantageous Effects

According to the present invention, an increase in sheet resistance can be minimized, as compared to a conventional blackening method, and the reflectivity of an electrically conductive pattern can be decreased by sufficiently blackening the electrically conductive pattern as well. Also, a blackening treatment of the electrically conductive pattern is easy, such that productivity can be improved, production costs can be reduced, and a manufacturing process can be performed in a short time, e.g., in units of second.

### DESCRIPTION OF DRAWINGS

The above and other aspects, features and other advantages of the present invention will be more clearly understood from the following detailed description taken in conjunction with the accompanying drawings, in which:

FIG. 1 is a cross-sectional view illustrating an electromagnetic wave shielding film including an electrically conductive pattern according to the present invention;

FIG. 2 is a graph showing the result of x-ray diffraction (XRD) measurements before and after the blackening of an electrically conductive pattern according to the present invention; and

FIG. 3 is a cross-sectional view illustrating an optical filter for a display device including an electromagnetic wave shielding film according to the present invention.

### BEST MODE

Exemplary embodiments of the present invention will now be described in detail with reference to the accompanying drawings.

A method for producing an electrically conductive pattern according to the present invention includes: forming an electrically conductive pattern on a substrate and blackening a surface of the electrically conductive pattern by immersing the electrically conductive pattern in a halogen solution to oxidize the surface of the electrically conductive pattern.

In the forming of the electrically conductive pattern, the substrate may be a glass substrate or a film formed of a polymer resin.

In the case of a glass substrate, the substrate may be formed of a glass-type optical filter positioned at a front of a plasma display panel (PDP), or may be the PDP itself. Herein, when the substrate is the PDP itself, the electrically conductive pattern is formed directly on the substrate constituting the plasma display panel.

When the substrate is a film formed of a polymer resin, the substrate may be a film-type optical filter positioned at the front of PDP, and may be a resin layer or a resin layer of an electromagnetic wave shielding film including an electrically conductive pattern formed on the resin layer.

When the film formed of a polymer resin is used as the substrate, the resin may be at least one selected from a polyacryl-based resin, a polyurethane-based resin, a polyester-based resin, a polyepoxy-based resin, a polyolefin-based resin, a polycarbonate-based resin, a cellulose-based resin, a polyimide-based resin, and a polyethylene naphthalate (PEN). Herein, the film-type substrate may be solid or flexible.

In the forming of the electrically conductive pattern, the electrically conductive pattern may include at least one metal selected from copper, silver, gold, and aluminum. Herein, the electrically conductive pattern may be formed using a conductive paste including the metal.

The conductive paste may be formed by dispersing metal powders in a predetermined organic solvent, and a polymer binder may be added to the organic solvent.

The metal powder is formed by pulverizing metal having excellent electrical conductivity. Although various metals may be applied in addition to the above-described types of metals, it is preferable to use silver powder, which has the lowest specific resistivity among the foregoing metals.

Butyl carbitol acetate, carbitol acetate, cyclohexanone, cellosolve acetate, terpineol or the like may be used as the organic solvent.

The polymer binder plays a role in allowing a conductive paste to have appropriate viscosity suitable for an offset printing method when the conductive paste is printed by the offset printing method, and also improving an adhesive force between an electrically conductive pattern formed by the conductive paste and the substrate.

The polymer resin may include a polyacryl-based resin, a polyurethane-based resin, a polyester-based resin, a polyepoxy-based resin, a polyolefin-based resin, a polycarbonate-based resin, a cellulose-based resin, a polyimide-based resin, and a polyethylene naphthalate (PEN) may be used as the polymer binder. In addition, various kinds of materials can be applied if they are similar in material to the substrate.

Also, when the glass substrate is used as the substrate, the conductive paste may further include a glass frit in order to improve the adhesive force between the conductive paste and the glass substrate.

To manufacture the conductive paste, for example, an organic binder resin solution is prepared by dissolving the polymer binder in an organic solvent, and the glass frit is added thereto. Finally, after adding the metal powder, the conductive paste may be manufactured by kneading and uniformly dispersing the agglomerated metal powder and glass frit using a three roll mill.

In the forming of the electrically conductive pattern, the electrically conductive pattern may be a silver (Ag) electrically conductive pattern which is formed by directly printing the conductive paste containing silver (Ag) powder onto the substrate.

A high temperature fired silver conductive paste may be used as the conductive paste when the substrate is the glass substrate. Herein, the high temperature may be 450° C. or more, and may preferably be 550° C. or more which is similar to a glass toughening condition.

When the substrate is a film formed of the polymer resin, a low temperature fired silver conductive paste may be used. Herein, the low temperature may be about 200° C. or less, and may be about 150° C. or less when the substrate is a polyethylene terephthalate (PET) film.

The electrically conductive pattern may be formed by printing the conductive paste on the substrate by any one method selected from an offset printing method, a screen printing method, a gravure printing method, and an inkjet printing method. Also, the electrically conductive pattern may be formed on the substrate using a photolithography method in addition to the foregoing methods.

The offset printing method among the above printing methods may include: filling an engraved portion formed at an engraved plate with a conductive paste; transferring the conductive paste to a printing blanket from the engraved portion of the engraved plate by bringing the printing blanket into contact with the engraved plate; and forming the electrically conductive pattern on the substrate by bringing the printing blanket into contact with the substrate and transferring the conductive paste to the substrate from the printing blanket.

In the filling of the engraved portion formed at an engraved plate with the conductive paste, the engraved portion may be filled with the conductive paste by injecting the conductive paste into the engraved portion, and after applying the conductive paste to the entire engraved plate, the engraved portion may be filled with the conductive paste by scraping the remainder of the conductive paste off the plate with a blade in order that the conductive paste fill, and be left only in the engraved portion.

Herein, although the present invention may use the engraved plate offset printing method, a flat plate offset printing method and a block plate offset printing method may be applicable to the present invention.

The conductive paste may be directly printed onto the substrate. However, in order to improve the adhesive force between the conductive paste and the substrate, a separate resin may be applied to the substrate, and thereafter the conductive paste may be printed onto the resin.

In addition, if it is a method capable of printing the conductive paste onto the substrate, all printing methods known in the art to which the present invention pertains may be used.

The method for producing the electrically conductive pattern according to the present invention may further include firing the electrically conductive pattern after the forming of the electrically conductive pattern on the substrate. After the firing of the electrically conductive pattern, the present invention may further include cooling the electrically conductive pattern.

In the firing of the electrically conductive pattern, the electrically conductive pattern may be fired at 550-800° C. for 30 seconds to 30 minutes. However, the present invention is not limited thereto.

In the cooling of the electrically conductive pattern, the fired electrically conductive pattern may be cooled by being left at room temperature or by having cold air supplied thereto. However, the present invention is not limited thereto.

In the blackening of the surface of the electrically conductive pattern, the halogen solution may include a halogen element selected from iodine (I₂), chlorine (Cl₂), bromine (Br₂), and fluorine (F₂).

The halogen element exists in a reducing ion state in the halogen solution. “Reducing ion” refers an ion which exhibits a phenomenon of having a lowered oxidation number due to receiving electrons from the electrically conductive pattern during contact with the electrically conductive pattern in the present invention.

Accordingly, in the blackening of the surface of the electrically conductive pattern, if the electrically conductive pattern is immersed in the halogen solution, the electrically conductive pattern is sufficiently blackened as the surface of the electrically conductive pattern is oxidized by a reduction of the reducing ion. That is, a blackened layer will be formed on the surface of the electrically conductive pattern, and the blackened layer formed thereon may be one of AgI, AgCl, AgBr, and AgF in a case in which the halogen solution includes a halogen element selected from I₂, Cl₂, Br₂, and F₂ and the electrically conductive pattern is a silver (Ag) electrically conductive pattern.

In the blackening of the surface of the electrically conductive pattern, the halogen solution may be prepared by mixing about 1-30 parts by weight of the halogen element and about 70-99 parts by weight of water based on 100 parts by weight of the halogen solution.

In the blackening of the surface of the electrically conductive pattern, the halogen solution may further include potassium iodide (KI). Although the blackening is not performed by KI itself, the blackening can be promoted by increasing the solubility of halogen anions, etc, when KI is further added in the halogen solution.

When the halogen solution further includes KI in the blackening of the surface of the electrically conductive pattern, the halogen solution may be manufactured by mixing about 0.5-30 parts by weight of the halogen element, about 0.5-30 parts by weight of the KI, about 40-99 parts by weight of water based on 100 parts by weight of the halogen solution.

Hereinafter, in the blackening of the surface of the electrically conductive pattern, a process of the blackening of the electrically conductive pattern will be described in more detail by immersing the electrically conductive pattern in the halogen solution.

When the electrically conductive pattern is immersed in the halogen solution, the halogen solution will oxidize the metal contained in the electrically conductive pattern. Accordingly, a halide will be formed as a blackened layer on the surface of the electrically conductive pattern. Herein, silver halide will be formed when the electrically conductive pattern is a silver (Ag) electrically conductive pattern.

Thus, the luster of the metal contained in the electrically conductive pattern will be diminished by the halide formed on the surface of the electrically conductive pattern, and the reflectivity thereof will be lowered.

As an example, when the electrically conductive pattern is a silver (Ag) electrically conductive pattern and an iodine aqueous solution, which contains I₂ as a halogen element having the largest oxidizing power on silver, is used as the halogen solution, silver is oxidized by a reduction of I₃⁻ existing in the iodine aqueous solution, such that a silver iodide (AgI) layer will be formed as the blackened layer.

Herein, since AgI+e⁻=Ag+I⁻ (E⁰=−0.152 V) and I₃⁻+2e⁻=3I⁻ (E⁰=0.535 V), it may be seen that 2Ag+I₃⁻→2AgI+I⁻ (E⁰=0.687 V). Therefore, it can be understood that the above reaction is a spontaneous reaction. At this time, it can be understood that the reducing power of I₃⁻ according to the addition of I₂ capable of oxidizing silver (Ag) is far more powerful on silver than the reducing power of the oxidizing power of KI alone and may be performed rapidly.

The blackening method according to the present invention is characterized in that it uses a reduction reaction according to a halogen anion component itself as described above. Therefore, in the blackened layer according to the present invention, the deeper the depth from the surface is, the less the iodine (I) component and the more the Ag content will be. Although the thickness of the blackened layer may be about 200 nm when measured by electron spectroscopy for chemical analysis (ESCA), it is not limited thereto. In this regard, the related art which uses a metal halide type ionic aqueous solution is different from the present invention in terms of using a reduction reaction by metal.

As described above, when using the iodine aqueous solution which contains I₂ as the halogen element having the largest oxidizing power on silver (Ag), the iodine aqueous solution may be manufactured by mixing solid iodine (I₂), KI having high solubility with respect to the solid iodine (I₂), and water.

At this time, the iodine aqueous solution may be manufactured by mixing about 0.5-30 parts by weight of iodine (I₂), about 0.5-30 parts by weight of KI, and about 40-99 parts by weight of water based on 100 parts by weight of the iodine aqueous solution. Herein, since the solid iodine has relatively low solubility with respect to water, the solid iodine becomes I₃⁻ to be easily dissolved in water if it is dissolved in the excess amount of a KI aqueous solution.

Accordingly, when the silver electrically conductive pattern is immersed in the iodine aqueous solution, silver iodide (AgI) is formed on the surface of the silver electrically conductive pattern as I₃⁻ contained in the iodine aqueous solution oxidizes silver (Ag) in the silver electrically conductive pattern. As a result, the luster of silver is diminished and the reflectivity thereof is decreased by the silver iodide.

In the blackening of the surface of the electrically conductive pattern, the electrically conductive pattern may be immersed in the halogen solution for 3-300 seconds. A desired degree of blackening is not easy to obtain if the immersion time is too short; and productivity may be reduced if the immersion time is too long. The degree of blackening is generally unrelated to the blackening immersion time, and the shorter the blackening time is, the smaller the increase in sheet resistance may be.

Cleaning the electrically conductive pattern blackened in the blackening of the surface of the electrically conductive pattern, and drying the electrically conductive pattern cleaned in the cleaning of the electrically conductive pattern may be further included.

In the cleaning of the electrically conductive pattern, the halogen solution remaining on the electrically conductive pattern may be washed off using a cleaning solution.

In the drying of the electrically conductive pattern, the electrically conductive pattern through the cleaning of the electrically conductive pattern may be dried at about 5° C. to about 120° C. for 3 minutes to 10 minutes.

The present invention provides an electrically conductive pattern produced according to the production method of the present invention.

The present invention provides a film including the electrically conductive pattern produced according to the production method of the present invention.

The present invention provides a film including: a substrate; an electrically conductive pattern provided on the substrate; and a blackened layer formed on a surface of the electrically conductive pattern by immersing the electrically conductive pattern in a halogen solution to oxidize the surface of the electrically conductive pattern. Since the entire contents of the foregoing embodiment are applied to the present embodiment, a detailed description thereof will be omitted below for simplicity of the description.

Herein, the film including the electrically conductive pattern may be an electromagnetic wave shielding film.

The present invention provides an optical filter for a display device including the electrically conductive pattern produced according to the production method of the present invention.

Herein, the optical filter for the display device may further include at least one selected from an anti-reflective layer that prevents external light, incident from the outside, from being reflected back to the outside, a near-infrared shielding layer for shielding near-infrared rays, and a color compensation layer that increases color purity by including color adjusting dyes to control color tone. Herein, the optical filter for the display device may be a glass-type or a film-type optical filter.

The present invention provides a display device including the electrically conductive pattern produced according to the production method of the present invention. Herein, although a plasma display device may exemplify the display device, it is not limited thereto.

The method for producing the electrically conductive pattern according to the present invention can be applied to various fields.

That is, an electromagnetic wave shielding film may be provided by forming the electrically conductive pattern according to the present invention on a film formed of a polymer resin. A display panel, in which the electrically conductive pattern is formed by directly forming the electrically conductive pattern on a substrate of the display panel, may be provided. A glass-type optical filter may be provided by forming the electrically conductive pattern on a glass substrate of the glass-type optical filter positioned at a front of the display panel. A film-type optical filter may be provided by forming the electrically conductive pattern on a film-type substrate of the film-type optical filter. Hereinafter, as an example, the present invention will be described in detail with reference to the electromagnetic wave shielding film employed in various fields.

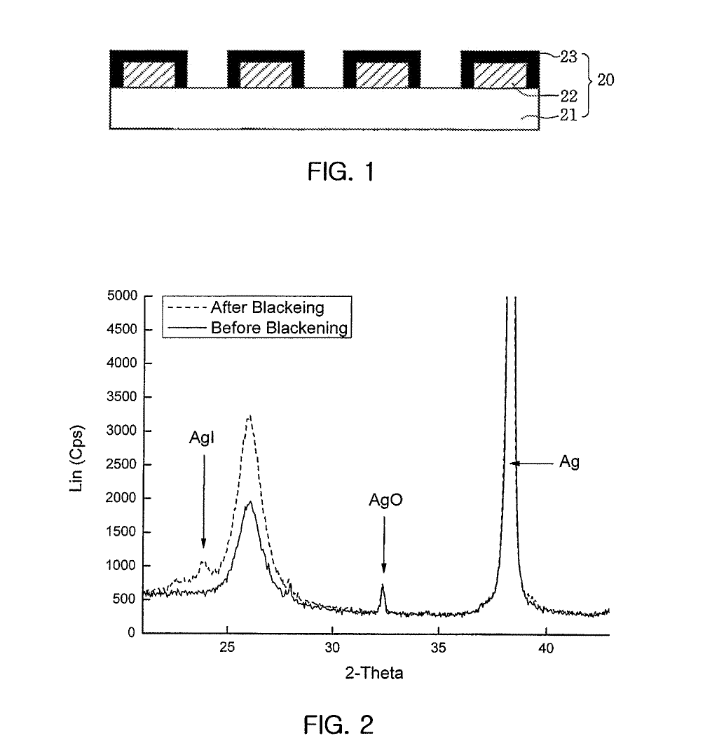

As shown in FIG. 1, an electromagnetic wave shielding film 20 according to the present invention includes a substrate 21, an electrically conductive pattern 22 formed on the substrate 21, and a blackened layer 23 formed on a surface of the electrically conductive pattern 22.

The electromagnetic wave shielding film 20 may be formed by forming the electrically conductive pattern 22 on the substrate 21, and blackening the surface of the electrically conductive pattern 22 by immersing the electrically conductive pattern 22 in a halogen solution to oxidize the surface of the electrically conductive pattern 22.

In the forming of the electrically conductive pattern, the electrically conductive pattern 22 is formed on the substrate 21 by printing a conductive paste on the substrate 21 by an engraved plate offset printing method.

After the forming of the electrically conductive pattern 22 on the substrate 21, firing and cooling the electrically conductive pattern 22 may be further included.

In the blackening of the surface of the electrically conductive pattern, the electrically conductive pattern 22 formed on the substrate 21 is immersed in the halogen solution for 3-300 seconds. The halogen solution oxidizes metal included in the electrically conductive pattern 22. Accordingly, a halide is formed on the electrically conductive pattern 22 as a blackened layer 23. For example, when the electrically conductive pattern 22 is a silver (Ag) electrically conductive pattern and an iodine aqueous solution containing iodine (I₂) is used as the halogen solution, a silver iodide (AgI) layer may be obtained as the blackened layer as silver is oxidized by strong reducing power of I₃⁻.

Meanwhile, the electromagnetic wave shielding film 20, for example, may be applied to an optical filter 100 positioned at a front of a plasma display panel of a plasma display device.

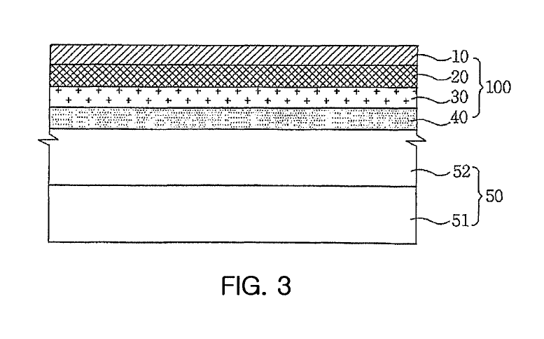

For example, as shown in FIG. 3, the optical filter 100, which is positioned at a front of a plasma display panel 50 having a rear panel 51 and a front panel 52, includes: a color compensation layer 40 that increases color purity by including color adjusting dyes to control color tone; a near-infrared shielding layer 30 that is stacked on the color compensation layer 40 and shields near-infrared rays generated from the plasma display panel 50 for preventing the malfunctioning of an electronic device such as a remote controller; the electromagnetic wave shielding film 20 according to the present invention that is stacked on the near-infrared shielding layer 30 and shields electromagnetic waves generated from the plasma display panel 50; an anti-reflective layer 10 that is stacked on the electromagnetic wave shielding film 20 and prevents external light, incident from the outside, from being reflected back to the outside.

Thus, if the optical filter 100, to which the electromagnetic wave shielding film 20 according to the present invention is applied, is positioned at the front of the plasma display panel 50, light from the plasma display panel 50 and the outside is reflected by the luster of the electrically conductive pattern with a metallic material, such that reduction of a contrast ratio of the display device is prevented by the blackened layer 23 formed on the electrically conductive pattern 22 of the electromagnetic wave shielding film 20.

Herein, although the present invention is described by applying to the plasma display panel 50, it is not limited thereto. Also, although the stacking sequence of the optical filter 100 positioned at the front of the plasma display panel 50 is described in sequence of the color compensation layer 40, the near-infrared shielding layer 30, the electromagnetic wave shielding film 20, and the anti-reflective layer 10, the stacking sequence is not limited thereto.

### MODE OF INVENTION

Hereinafter, the present invention will be described in more detail through examples. However, the scope of the present invention is not limited to the following examples.

### Example 1

A silver (Ag) conductive paste (100 parts by weight), including about 75 parts by weight of silver powder, about 12 parts by weight of ethyl cellulose as a binder, about 12 parts by weight of butyl carbitol acetate as a solvent, and about 1 part by weight of glass frit, was printed as a mesh-type pattern on a glass substrate by using an engraved plate offset printing method. Accordingly, a mesh-type silver electrically conductive pattern was obtained.

The mesh-type silver electrically conductive pattern, which has the printing width of about 25 μm and a silver iodide (AgI) layer formed on a surface, was obtained by cooling after firing the pattern at about 60° C. for about 10 minutes.

Subsequently, after dissolving about 10 g of KI and about 2 g of I₂ in about 100 g of water, an iodine aqueous solution was manufactured by stirring for about 10 minutes, and the silver electrically conductive pattern was immersed in the iodine aqueous solution for about 3 seconds.

Accordingly, the silver iodide layer was formed as a blackened layer on the surface of the mesh-type silver electrically conductive pattern by I₃⁻ of the iodine aqueous solution.

### Examples 2-4

Electrically conductive patterns were produced by the same method as the Example 1 except that immersion times were about 10 seconds, 20 seconds, and 30 seconds.

### Comparative Example 1

A silver (Ag) conductive paste (100 parts by weight), including about 75 parts by weight of silver powder, about 12 parts by weight of ethyl cellulose as a binder, about 12 parts by weight of butyl carbitol acetate as a solvent, and about 1 part by weight of glass frit, was printed as a mesh-type pattern on a glass substrate by using an engraved plate offset printing method. Accordingly, the mesh-type silver electrically conductive pattern was obtained.

The mesh-type silver electrically conductive pattern, which had a printing width of about 25 μm and a silver iodide (AgI) layer formed on a surface, was obtained by cooling after firing the pattern at about 600° C. for about 10 minutes.

Physical Properties Evaluation

Sheet resistances (Q/□) of the mesh-type silver (Ag) electrically conductive patterns according to Examples 1-4 and Comparative Example 1 were measured by using a MCP-T600 from Mitsubishi Chemical Corporation. After measuring the reflectivities (550 nm) of the mesh-type silver electrically conductive patterns using a UV-3600 from Shimadzu Corporation, degrees of blackening (L values) were calculated from the reflectivities. These were presented in Tables 1 and 2.

TABLE 1

| | | | Mesh surface after blackening | | |
|---|---|---|---|---|---|
| | | | 550 nm | Degree of | Sheet |
| | Immersion | | Reflectivity | blackening | resistance |
| | time | | (%) | (L) | (Ω/□) |
| Example 1 | 3 seconds | Mesh | 8.4 | 34.9 | 0.38 |
| | | surface | | | |
| | | Glass | 9.3 | 36.7 | |
| | | surface | | | |
| Example 2 | 10 seconds | Mesh | 8.2 | 34.4 | 0.51 |
| | | surface | | | |
| | | Glass | 9.2 | 36.4 | |
| | | surface | | | |
| Example 3 | 20 seconds | Mesh | 8.3 | 34.7 | 0.77 |
| | | surface | | | |
| | | Glass | 9.2 | 36.5 | |
| | | surface | | | |
| Example 4 | 30 seconds | Mesh | 8.5 | 35.0 | 1.15 |
| | | surface | | | |
| | | Glass | 8.9 | 35.9 | |
| | | surface | | | |

TABLE 2

| | | | Mesh surface without blackening | | |
|---|---|---|---|---|---|
| | | | treatment | | |
| | | | 550 nm | Degree of | Sheet |
| | Immersion | | Reflectivity | blackening | resistance |
| | time | | (%) | (L) | (Ω/□) |
| Comparative | 0 seconds | Mesh | 18.1 | 49.6 | 0.28 |
| Example 1 | | surface | | | |
| | | Glass | 9.4 | 36.8 | |
| | | surface | | | |

As shown in Tables 1 and 2, the sheet resistance of the silver electrically conductive pattern without blackening treatment as a Comparative Example was about 0.28Ω/□, and in the case of the Examples 1-4, when the silver iodide (AgI) layer was formed as the blackened layer on the silver electrically conductive pattern using the iodine aqueous solution, the sheet resistances were about 0.38, 0.51, 0.77 and 1.15Ω/□, respectively. Therefore, the sheet resistances were increased about 136-359% as compared to the Comparative Example 1 without the blackening treatment.

In case of the degree of blackening (L value), it denotes that the smaller the L value is, the blacker it is. Although the degree of blackening (L value) of the silver electrically conductive pattern was about 49.6 in the case of comparative example 1, the degrees of blackening (L values) were decreased to about 34.9, 34.4, 34.7, and 35.0 when the silver iodide (AgI) layer was formed as the blackened layer on the silver electrically conductive pattern using the iodine aqueous solution in the case of the Examples 1-4. Therefore, it can be confirmed that the silver electrically conductive patterns 22 of the Examples 1-4 are sufficiently blackened according to the above result.

Thus, according to the present invention, an increase in sheet resistance can be minimized as well as a sufficient degree of blackening provided within a few seconds.

The reflectivity (%) of the silver electrically conductive pattern was about 18.1% in the case of the Comparative Example 1, and the reflectivities were about 8.4, 8.2, 8.3, and 8.5% when the silver iodide (AgI) layer was formed as the blackened layer on the silver electrically conductive pattern using the iodine aqueous solution in the case of the Examples 1-4. Therefore, it can be understood that the reflectivities are decreased about 55% as compared to the Comparative Example 1 which is before the blackening treatment. Herein, it can be understood that the reflectivity is not greatly affected by changes in the immersion time.

Thus, according to the present invention, the reflectivity of the silver electrically conductive pattern 22 can be greatly decreased.

As shown in FIG. 2 that presents the result measured with regard to the surface of the silver (Ag) electrically conductive pattern 22 using an X-ray diffractometer by which existence of a material is presented in terms of a peak positioned at a specific angle, it can be understood that the reasons for which the degree of blackening is decreased and the reflectivity is lowered in the case of the Examples 1-4, are because of the silver iodide layer (AgI) formed on the surface of the silver electrically conductive pattern. That is, silver (Ag) luster of the silver electrically conductive pattern is removed by the silver iodide (AgI) layer so that the reflectivity thereof will be lowered.

Thus, according to the present invention, when the surface of the electrically conductive pattern is blackened by oxidizing the electrically conductive pattern with the halogen solution after forming the electrically conductive pattern on the substrate, the electrically conductive pattern can be sufficiently blackened and the reflectivity thereof can be lowered.

The sheet resistance after the blackening treatment is not only increased within a narrow range as compared to the sheet resistance before the blackening treatment, but the production method is also simplified. Therefore, productivity can be improved and production cost can be reduced.

When the conductive paste is printed on the substrate by the offset printing method according to the present invention, the electrically conductive pattern can be easily formed on the substrate such that production is simplified, productivity is improved, and production costs are reduced.

While the present invention has been shown and described in connection with the exemplary embodiments, it will be apparent to those skilled in the art that modifications and variations can be made without departing from the spirit and scope of the invention as defined by the appended claims.

1. A method for producing an electrically conductive pattern, the method comprising:
forming an electrically conductive pattern on a substrate; and
blackening a surface of the electrically conductive pattern by immersing the electrically conductive pattern in a halogen solution to oxidize the surface of the electrically conductive pattern.

2. The method of claim 1, wherein, in the forming of the electrically conductive pattern, the substrate is a glass substrate or a film formed of a polymer resin.

3. The method of claim 1, wherein, in the forming of the electrically conductive pattern, the electrically conductive pattern comprises at least one metal selected from the group consisting of copper, silver, gold, and aluminum.

4. The method of claim 1, wherein, in the forming of the electrically conductive pattern, the electrically conductive pattern is a silver (Ag) electrically conductive pattern which is formed by directly printing conductive paste containing silver (Ag) powder on the substrate.

5. The method of claim 1, wherein, in the forming of the electrically conductive pattern, the electrically conductive pattern is formed by printing the conductive paste on the substrate by any one method selected from the group consisting of an offset printing method, a screen printing method, a gravure printing method, and an inkjet printing method.

6. The method of claim 1, wherein, in the blackening of the surface of the electrically conductive pattern, the halogen solution comprises a halogen element selected from the group consisting of iodine (I₂), chlorine (Cl₂), bromine (Br₂), and fluorine (F₂).

7. The method of claim 6, wherein, in the blackening of the surface of the electrically conductive pattern, the halogen solution is manufactured by mixing 1-30 parts by weight of the halogen element and 70-99 parts by weight of water based on 100 parts by weight of the halogen solution.

8. The method of claim 6, wherein, in the blackening of the surface of the electrically conductive pattern, the halogen solution further comprises potassium iodide (KI).

9. The method of claim 8, wherein, in the blackening of the surface of the electrically conductive pattern, the halogen solution is manufactured by mixing 0.5-30 parts by weight of the halogen element, about 0.5-30 parts by weight of the KI, 40-99 parts by weight of water based on 100 parts by weight of the halogen solution.

10. The method of claim 1, wherein, in the blackening of the surface of the electrically conductive pattern, the halogen solution is manufactured by mixing 0.5-30 parts by weight of iodine (I₂), 0.5-30 parts by weight of KI, and 40-99 parts by weight of water based on 100 parts by weight of the halogen solution.

11. The method of claim 1, wherein, in the blackening of the surface of the electrically conductive pattern, the electrically conductive pattern is immersed in the halogen solution for 3-300 seconds.

12. The method of claim 1, further comprising:
cleaning the electrically conductive pattern blackened during the blackening of the surface of the electrically conductive pattern; and
drying the electrically conductive pattern cleaned during the cleaning of the electrically conductive pattern.

13. An electrically conductive pattern produced by the methods according to claim 1.

14. An optical filter for a display device comprising the electrically conductive pattern according to claim 13.

15. A display device comprising the electrically conductive pattern according to claim 13.

16. A film comprising:
a substrate;
an electrically conductive pattern provided on the substrate; and
a blackened layer formed on a surface of the electrically conductive pattern by immersing the electrically conductive pattern in a halogen solution to oxidize the surface of the electrically conductive pattern.

17. The film of claim 16, wherein the electrically conductive pattern comprises at least one metal selected from the group consisting of copper, silver, gold, and aluminum.

18. The film of claim 16, wherein the halogen solution comprises a halogen element selected from the group consisting of iodine (I₂), chlorine (Cl₂), bromine (Br₂), and fluorine (F₂).

19. The film of claim 18, wherein the halogen solution further comprises potassium iodide (KI).

20. The film of claim 16, wherein the electrically conductive pattern is a silver (Ag) electrically conductive pattern, and the blackened layer is iodide silver (AgI) formed by immersing the silver electrically conductive pattern in the halogen solution containing iodine (I₂), KI, and water.
